(19) United States
(12) Patent Application Publication
(10) Pub. No.: US 2023/0395632 A1
(43) Pub. Date: Dec. 7, 2023

(54) HETEROGENEOUSLY SUBSTRATE-BONDED OPTICAL ASSEMBLY AND METHOD OF MANUFACTURING THE SAME

(71) Applicant: Egis Technology Inc., Hsinchu City (TW)

(72) Inventor: BRUCE C. S. CHOU, Hsinchu City (TW)

(21) Appl. No.: 18/166,371

(22) Filed: Feb. 8, 2023

Related U.S. Application Data
(60) Provisional application No. 63/332,280, filed on Apr. 19, 2022.

(30) Foreign Application Priority Data
Dec. 9, 2022 (CN) 202211587446.X

(51) Int. Cl. H01L 27/146

(52) U.S. Cl. CPC H01L 27/14634; H01L 27/14632; H01L 27/14636; H01L 27/1465; H01L 27/14685; H01L 27/14687; H01L 27/1469; H01L 27/14623; H01L 27/14689

(57) ABSTRACT

A heterogeneously substrate-bonded optical assembly includes a processor chip, an optical chip and a molding compound layer. The processor chip includes: a processor circuit; reader circuits electrically connected to the processor circuit; a first protection layer disposed on the processor circuit and the reader circuits; and first vias penetrating through first protection layer and being electrically connected to the reader circuit. The optical chip includes: a second protection layer bonded to the first protection layer; second vias penetrating through the second protection layer and being bonded to the first vias; and optical pixels electrically connected to the reader circuit respectively through the second vias and the first vias. The molding compound layer surrounds the optical chip and is disposed on the first protection layer. A method of manufacturing the optical assembly applicable to high-resolution applications is also disclosed.

### CROSS-REFERENCE TO RELATED APPLICATIONS

This application claims priorities of U.S. Provisional Patent Application Ser. No. 63/332,280, filed on Apr. 19, 2022; and China Patent Application Ser. No. 202211587446.X, filed on Dec. 9, 2022, the entire contents of which are hereby incorporated by reference.

### BACKGROUND OF THE INVENTION

### Field of the Invention

This disclosure relates to an optical assembly and a method of manufacturing the same, and more particularly to a heterogeneously substrate-bonded optical assembly and a method of manufacturing the same.

### Description of the Related Art

Infrared (IR) light is invisible light, which ranges between micro waves and visible light and is an electromagnetic wave having a wavelength ranging from 0.76 microns (μm) to 1,000 μm. The thermal radiation outputted from an object at the room temperature also substantially falls within this band. Recently, an infrared array element can provide auxiliary depth sensing information for a two-dimensional (2D) image, so that the 2D image can be processed into a three-dimensional (3D) image or added with depth information. A distance from a light-emitting source to the object can be calculated according to the light of the light-emitting source (more particularly a laser source) emitted to the object and reflected from the object. However, the light-emitting source may injure human eyes. Therefore, the light-emitting source and the sensor need to operate for the light having the wavelength longer than 1 μm, or even longer than 1.3 μm, and the so-called eye-safe light-emitting source is thus required.

A visible light sensor device, such as a complementary metal-oxide semiconductor (CMOS) image sensor manufactured from a silicon wafer, has been well developed at present, wherein the integration of high-resolution pixels of the array element and associated read/processor circuit has reached a fairly mature stage with the development of the silicon wafer technology (Moore's Law). However, under the restriction of the quantum energy level of the silicon material, the conventional silicon-based infrared sensor has the low quantum efficiency (QE) and cannot be effectively applied to the sensing of the infrared light having the wavelength longer than 1 μm.

A non-silicon based material (e.g., InGaAs) has the energy level lower than that of silicon, and is more suitable for the infrared light having the longer wavelength. The energy level can be adjusted to select the wavelength (longer than 1 μm, or even longer than 1.1 μm, 1.2 μm or 1.3 μm) to be detected according to the composition ratio of the three elements.

However, the infrared array element (e.g., 8×8, 100×100 or even larger array element) needs complicated sensing pixels and read/processor circuits to be integrated, wherein each pixel has a light sensing cell and a corresponding reader circuit. So, it is very difficult to combine the pixel array chip with the reader/processor circuit chip by way of conventional wire bonding, and the only way is to integrate them together in a manner similar to that for the silicon-based CMOS image sensor. However, as mentioned hereinabove, the silicon material cannot effectively sense the infrared light having the wavelength longer than 1 μm, but can be used to manufacture the complicated reader/processor circuits. The non-silicon based material can be used to manufacture the good long-wavelength sensor, which cannot be easily integrated with the reader/processor circuits to form the high-density array sensing members.

### BRIEF SUMMARY OF THE INVENTION

It is therefore an objective of this disclosure to provide a heterogeneously substrate-bonded optical assembly and a method of manufacturing the same, wherein a first assembly containing array elements is manufactured using a non-silicon wafer, and a second assembly containing read-processing circuits is manufactured using a silicon wafer. Then, the first and second assemblies are bonded together in conjunction with a molding compound and subsequent manufacturing processes to manufacture the heterogeneously substrate-bonded optical assembly applicable to high-resolution and long-wavelength infrared light sensing or other optical processing.

To achieve the above-identified objective, this disclosure provides a heterogeneously substrate-bonded optical assembly including a processor chip, an optical chip containing a non-silicon substrate and a molding compound layer. The processor chip includes: a silicon-containing substrate; a processor circuit; reader circuits electrically connected to the processor circuit; a first protection layer disposed on the processor circuit and the reader circuits; and first vias penetrating through the first protection layer and being electrically connected to the reader circuits. The optical chip includes: a second protection layer bonded to the first protection layer; second vias penetrating through the second protection layer and being bonded to the first vias; and optical pixels formed in the non-silicon substrate and electrically connected to the reader circuits respectively through the second vias and the first vias. The optical pixels correspond to the reader circuits in a one-to-one manner. A transversal dimension of the processor chip is greater than a transversal dimension of the optical chip. The molding compound layer surrounds the optical chip and is disposed on the first protection layer. The molding compound layer has a top surface flush with a backside of the optical chip.

This disclosure also provides a method of manufacturing a heterogeneously substrate-bonded optical assembly. The method includes steps of: providing initial optical chips and a processing wafer, wherein: each of the initial optical chips includes: a non-silicon substrate layer; optical pixels formed on the non-silicon substrate layer; a second protection layer formed on the optical pixels; and second vias penetrating through the second protection layer and electrically connected to the optical pixels, respectively; and the processing wafer has processor chips each including: a silicon-containing substrate; a processor circuit; reader circuits electrically connected to the processor circuit; a first protection layer disposed on the processor circuit and the reader circuits; and first vias penetrating through the first protection layer; respectively flipping and bonding the initial optical chips to the processor chips in an aligned manner, so that the optical pixels are electrically connected to the reader circuits through the second vias and the first vias, respectively; forming a molding compound structure layer on the initial optical chips and the processor chips; removing a portion of the molding compound structure layer and a portion of each of the initial optical chips; and dicing the molding compound structure layer and separating the processor chips to form optical assemblies, wherein in each of the optical assemblies, the optical pixels correspond to the reader circuits in a one-to-one manner, and a transversal dimension of the processor chip is greater than a transversal dimension of the initial optical chip.

With the above-mentioned embodiments, the complicated read-processing circuits can be manufactured on the silicon wafer, the infrared light sensors are manufactured using the non-silicon wafer, and then the sensors and the read-processing circuits are combined together, so that the high-resolution and low-cost long-wavelength infrared light sensors or other optical processors can be manufactured by wafer-level manufacturing processes in a mass production manner.

In order to make the above-mentioned content of this disclosure more obvious and be easily understood, preferred embodiments will be described in detail as follows in conjunction with the accompanying drawings.

### BRIEF DESCRIPTION OF THE SEVERAL VIEWS OF THE DRAWINGS

FIG. 1 is a schematic structure view showing an optical assembly according to a preferred embodiment of this disclosure.

FIG. 2 is a schematic structure view showing a modified example of the optical assembly of FIG. 1.

FIGS. 3 to 8 are schematic views showing structures in steps of a method of manufacturing the optical assembly of FIG. 1.

FIGS. 9 and 10 are schematic structure views showing a modified example of FIGS. 7 and 8.

### DETAILED DESCRIPTION OF THE INVENTION

In this disclosure, optical chips are manufactured from a non-silicon wafer, processor chips each including reader and processor circuits are manufactured from a silicon wafer, and the non-silicon wafer is diced into the optical chips, which are respectively aligned with the corresponding processor chips and bonded to the silicon wafer. Therefore, the technology of bonding non-silicon sensing chips onto the silicon wafer is adopted in this disclosure, and may further be referred to as sensing-chip-on-wafer. After the optical chips have been bonded to the wafer having the corresponding processor circuits, molding compound infusion, partial molding compound grinding/polishing and even partial backside grinding/polishing of the optical chips may be performed to form a pseudo silicon wafer, which has a flat surface including a backside of the partial optical chip and a molding compound surrounding a periphery of the optical chip. Then, other subsequent manufacturing processes, such as testing, dicing and packaging processes, can be performed on the pseudo silicon wafer in a manner similar to that of the conventional silicon wafer, or even a wafer-level optical assembly, such as an optical sensor device, an optical filter, a polarizer, a curved-surface optical device, free form optics, a digital optical device, a diffraction optical element (DOE), a metalens and the like, can be manufactured in a wafer-level manner, so that an optical processing structure or an optical processor can be manufactured. The optical sensor device can be applied to the sensing of the long-wavelength infrared light and any wavelength of light, and can provide the high-resolution sensing effect. It is worth noting that each of all the structure layers may be constituted by one single layer of material or multiple layers of materials.

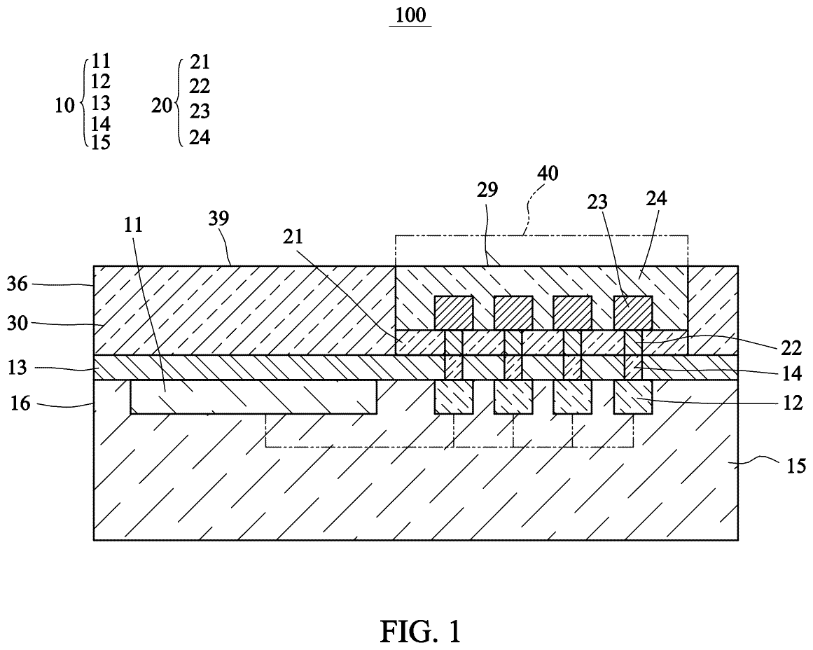

FIG. 1 is a schematic structure view showing an optical assembly according to a preferred embodiment of this disclosure. Referring to FIG. 1, this embodiment provides a heterogeneously substrate-bonded optical assembly 100 including a processor chip 10, an optical chip 20 and a molding compound layer 30.

The processor chip 10 includes a processor circuit 11, reader circuits (or reader pixels) 12, a first protection (or passivation) layer 13 and first vias 14. The processor circuit 11 further includes an interface circuit for communicating with an external electronic system. The processor circuit 11 and the reader circuits 12 are circuits formed in or on a silicon-containing substrate 15, and the reader circuits 12 are electrically connected to the processor circuit 11 through metal interconnection wires formed in the CMOS manufacturing process. Therefore, the processor circuit 11 and the reader circuits 12 may be regarded as a read-processing circuit. It is understandable that the silicon-containing substrate 15 may include a silicon substrate and one or multiple metal layers, dielectric layers and protection layers formed thereabove or thereon. The first protection layer 13 is disposed on the processor circuit 11 and the reader circuits 12. The first vias 14 penetrate through the first protection layer 13, and are electrically connected to the reader circuits 12 of the read-processing circuit, and may be formed by etching the first protection layer 13 to form windows, into which an electroconductive material, such as a metallic material (including copper, tungsten and the like), or a non-metallic material (including a polysilicon material and the like), is filled.

The optical chip 20 includes a second protection layer 21, second vias 22 and optical pixels 23. The optical pixel 23 can provide the optical processing functions including, for example but without limitation to, light receiving, light emitting, filtering, polarizing, focusing, defocusing, reflecting, diffracting and the like, and a combination thereof. In the non-limiting examples to be detailed hereinbelow, the optical pixel 23 is a sensing pixel having the light-receiving function for sensing light and thus generating an electric signal, and the reader circuit 12 provides a reading signal for reading out the electric signal of the sensing pixel. The second protection layer 21 is disposed on the first protection layer 13. As mentioned hereinabove, each of the first protection layer 13 and the second protection layer 21 may be made of one single layer of material or multiple layers of materials, and may be widely understood as including conductor layers, dielectric layers and metal plug materials used in all back-end metal processes of a wafer manufacturing process. The second vias 22 penetrate through the second protection layer 21 and are bonded to the first vias 14, wherein aligned bonding may be performed to achieve electrical connections.

In this embodiment, the optical chip 20 further includes a substrate 24 being a non-silicon substrate (or referred to as a non-silicon substrate). In a non-restrictive example, the material of the substrate 24 is an III-V semiconductor compound, such as gallium arsenide (GaAs), indium phosphide (InP), gallium nitride (GaN) and the like. A partial material of the optical pixel 23 formed on the substrate 24 may be, for example, indium arsenide gallium (InGaAs), aluminum gallium arsenide (InAlAs) and the like. The optical pixels 23 formed in the substrate 24 are electrically connected to the reader circuits 12 respectively through the second vias 22 and the first vias 14. Each of the optical pixels 23 is for sensing the infrared light having the wavelength longer than 1 μm (or even 1.3 μm), and thus generates the corresponding electric signal. The reader circuit 12 reads the electric signal, and the read electric signal is transmitted to the processor circuit 11 for image signal processing. In one example, the outermost surface of the first protection layer 13 is made of the material of silicon oxide or silicon dioxide, and the outermost surface of the second protection layer 21 is also made of the material of silicon oxide, silicon dioxide, and other materials, such as silicon nitride, metal oxide and the like. Therefore, hybrid bonding is adopted in the wafer-level manufacturing process, so that the silicon oxide is bonded to the silicon oxide, and the vias are bonded to the vias (hereinafter referred to as via-to-via (VTV) bonding. The silicon oxide bonded to the silicon oxide is performed using the fusion bonding technology of treating the silicon oxide surfaces into polar surfaces with hydrogen bonds, so that the two surfaces can be bonded together, and the high-temperature treatment is performed to form the bonding layer with the high strength oxide. Herein, the VTV bonding is metal atom diffusion bonding, wherein clean metal surfaces contact each other in a high-temperature process, and the metal atoms interdiffuse to form bonds. Therefore, the hybrid bonding bonds the first protection layer 13 to the second protection layer 21, and bonds the first vias 14 to the second vias 22, so that the bonding interface can achieve the effects of electrically connecting the first vias 14 to the corresponding second vias 22, insulating the neighboring first vias 14, and insulating the neighboring second vias 22. Also, the electroconductive interface between the first vias 14 and the second vias 22 and the insulation interface between the first protection layer 13 and the second protection layer 21 are disposed on a same plane.

The molding compound layer 30 surrounds the optical chip 20 and is disposed on the first protection layer 13 to firmly fix the optical chip 20 and the processor chip 10 together. Because the wafer-level manufacturing process is adopted, the molding compound layer 30 has a molding compound structure having a dicing mark or dicing marks formed by wafer-level package dicing. In addition, a vertical boundary 36 of the molding compound layer 30 is aligned with a vertical boundary 16 of the processor chip 10 after dicing. It is understandable that this disclosure is not restricted thereto, but has the basic architecture that the transversal dimension of the processor chip is greater than the transversal dimension of the optical chip. In one embodiment, the molding compound layer 30 has a property of shielding the infrared light. That is, the infrared light cannot transmit or penetrate through the molding compound layer 30 to prevent the stray light from entering the optical pixel 23 due to the coupling of the molding compound layer 30. More particularly, the infrared light has the wavelength shorter than or equal to 20 μm, 12 μm or 5 μm.

Because this disclosure relates to the technology of correspondingly bonding the optical pixels to the reader pixels (circuits) in a one-to-one manner, the area of each via is preferably smaller. Thus, the transversal dimension of each first via 14 is smaller than or equal to 1 μm, and the transversal dimension of each optical pixel 23 is smaller than or equal to 10 μm, or even 8, 6 and 5 μm. In this example, the transversal dimension of the first via 14 is equal to the transversal dimension of the second via 22. Of course, the transversal dimension of the first via 14 may be different from the transversal dimension of the second via 22 in order to avoid the alignment error, wherein one transversal dimension may be greater than the other transversal dimension.

In this embodiment, the molding compound layer 30 surrounds the substrate 24, and has a top surface 39 flush with a backside 29 of the optical chip 20 (or substrate 24). The substrate 24 is the structure left after the substrate, which is necessary for the formations of the second vias 22 and the optical pixels 23, has been partially removed, wherein the explanation will be provided later. The substrate 24 allows the long-wavelength infrared light to penetrate or transmit therethrough, and this property cannot be achieved by the silicon substrate. Therefore, the substrate 24 is also an important part of the optical assembly of this disclosure, and allows the incident infrared light to transmit therethrough and directly reach the optical pixel 23. In addition, the optical assembly 100 may further include an optical structure 40 disposed on the backside 29 of the optical chip 20. The optical structure 40, or a combination of the optical structure 40 and the substrate 24 includes, for example but without limitation to, optical devices, such as collimators, micro lenses, filters, partial light shielding layers and the like, or a combination thereof. In addition, these optical devices correspond to the optical pixels 23 in a one-to-one, one-to-many or many-to-many relationship.

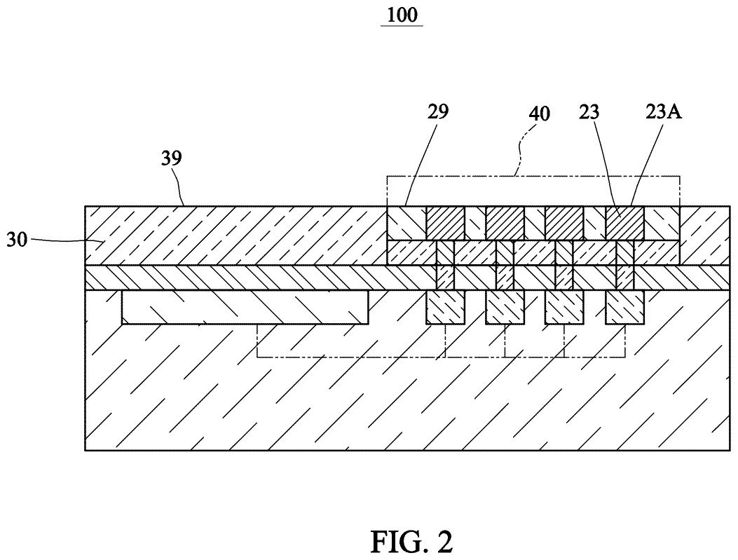

FIG. 2 is a schematic structure view showing a modified example of the optical assembly of FIG. 1. Referring to FIG. 2, this example is similar to FIG. 1, and descriptions of symbols thereof the same as those of FIG. 1 may be found in parts corresponding to the FIG. 1. The difference between FIGS. 2 and 1 resides in that the substrate 24 (FIG. 1) on the backside of the optical pixel 23 has been completely removed to form the structure of FIG. 2, thereby decreasing the thickness of the optical assembly 100, and increasing the sensitivity of the optical pixel. In this case, the optional optical structure 40 is disposed on the optical pixels 23, and the top surface 39 of the molding compound layer 30, the backsides 23A of the optical pixels 23 and the backside 29 of the optical chip 20 are disposed on a same plane or at the same level (height).

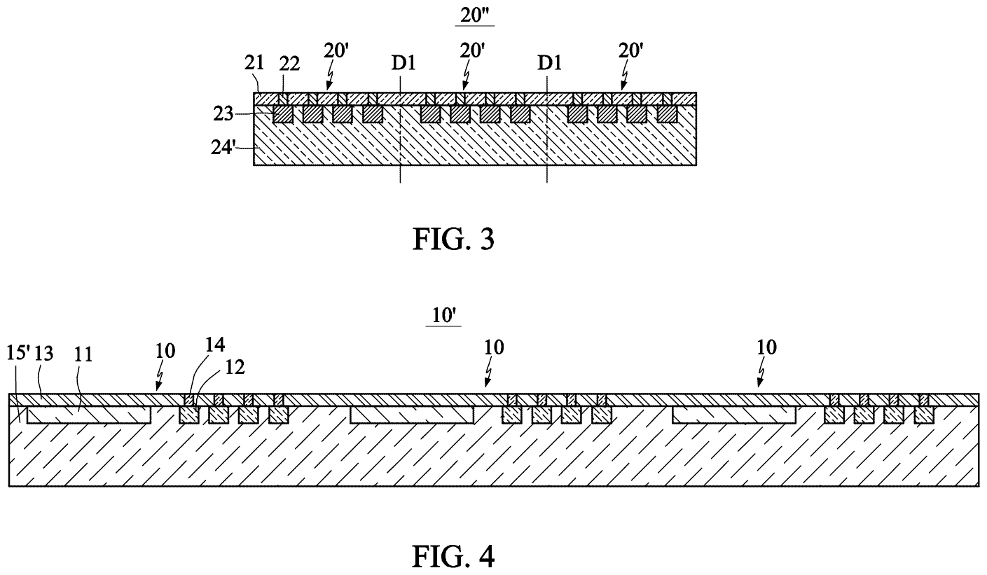

FIGS. 3 to 8 are schematic views showing structures in steps of a method of manufacturing the optical assembly 100 of FIG. 1. The method of manufacturing the optical assembly includes the following steps. First, as shown in FIGS. 3 and 4, a processing wafer 10′ and initial optical chips 20′ are provided. Referring to FIG. 3, the initial optical chips 20′ may be formed together in a non-silicon wafer 20″, for example, and the backsides thereof can be planarized by way of chemical mechanical grinding/polishing. Then, the initial optical chips 20′ can be obtained by way of dicing along scribing lines D1. Each initial optical chip 20′ includes a substrate layer 24′ (non-silicon substrate layer), optical pixels 23, a second protection layer 21 and second vias 22. The optical pixels 23 are formed in the substrate layer 24′, which allows the light (e.g., long-wavelength infrared light) to transmit therethrough in the light sensing application. The substrate 24 corresponding to FIG. 1 is an infrared light-transmitting substrate. The second protection layer 21 is formed on the optical pixels 23. The second vias 22 penetrate through the second protection layer 21, and are respectively electrically connected to the optical pixels 23.

Referring to FIG. 4, the processing wafer 10′ has the processor chips 10. Each processor chip 10 includes a processor circuit 11, reader circuits 12, a first protection layer 13 and first vias 14. The reader circuits 12 are electrically connected to the processor circuit 11. The first protection layer 13 is disposed on the processor circuit 11 and the reader circuits 12. The first vias 14 penetrate through the first protection layer 13. In order to provide a flat surface, chemical mechanical grinding/polishing may be performed to planarize the backside of the processing wafer 10′. It is understandable that a silicon-containing wafer 15′ may be adopted and silicon-wafer treating processes can be performed to form the above-mentioned structure. In addition, the main body of the silicon-containing wafer 15′ is the silicon wafer, and may include other protection/passivation layers, oxide layers or wire layers. In another example, the silicon-containing wafer 15′ may have no other protection layer or oxide layer.

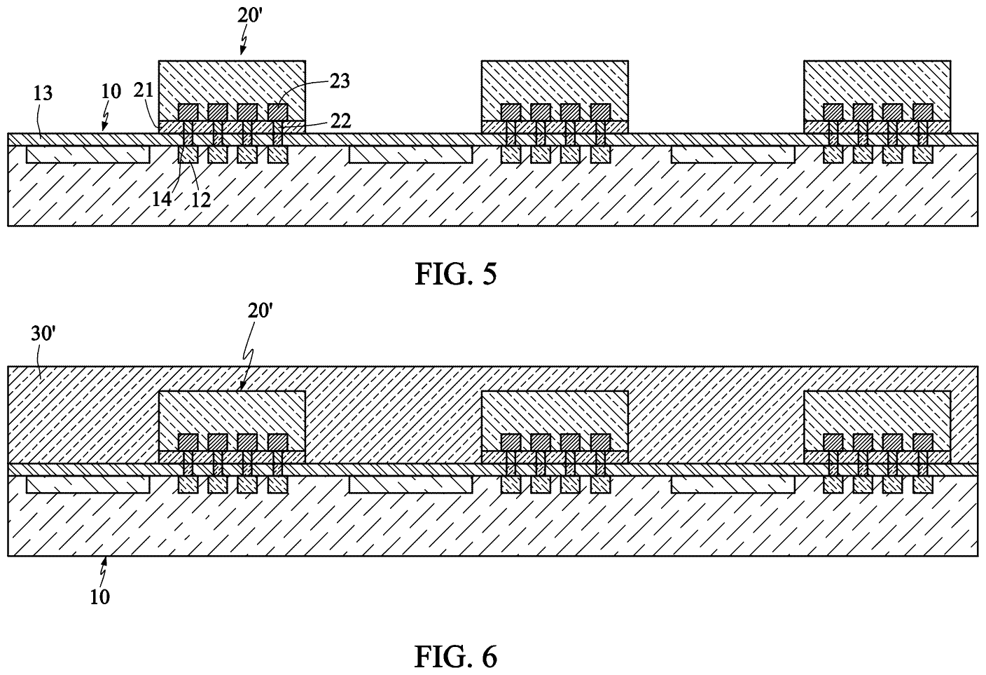

Then, as shown in FIG. 5, the initial optical chips 20′ are respectively flipped (inverted) and bonded to the processor chips 10 in an aligned manner in a manner of bonding the optical chips to the silicon wafer (defined as heterogeneous substrate bonding), so that the optical pixels 23 are electrically connected to the reader circuits 12 through the second vias 22 and the first vias 14, respectively. In this example, the transversal dimension of the initial optical chip 20′ is smaller than the transversal dimension of the processor chip 10, so a gap is present between adjacent two of the initial optical chips 20′. In one example, hybrid bonding is adopted, so that the first protection layer 13 is fusion-bonded to the second protection layer 21, and the first vias 14 is diffusion-bonded to the second vias 22 by way of direct metal-metal (e.g., copper-copper or tungsten-tungsten) diffusion bonding. In another example, the bonding interface between the first via 14 and the second via 22 may be a solder bonding interface.

Next, as shown in FIG. 6, a molding compound structure layer 30′ is formed on the initial optical chips 20′ and the processor chips 10 using a molding compound, so that the molding compound covers the initial optical chips 20′ and the processor chips 10. In one example, compressive overmolding is adopted to achieve the above-mentioned operation. Thus, the initial optical chips 20′ and the processor chips 10 are well fixed to facilitate the subsequent grinding/polishing process.

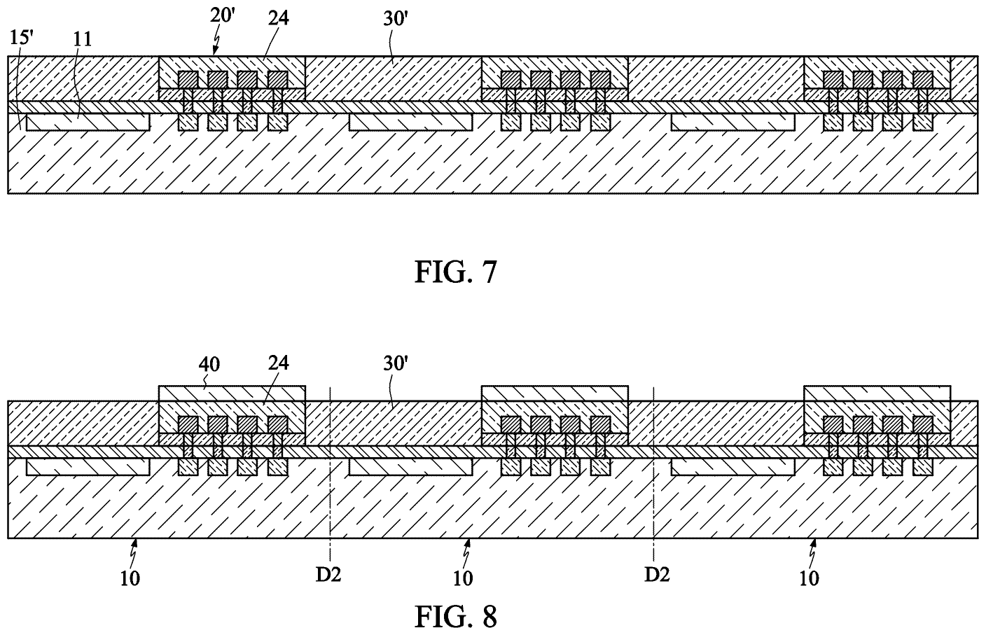

Then, as shown in FIG. 7, a portion of the molding compound structure layer 30′ and a portion of each of the initial optical chips 20′ are removed. At this time, the overall structure of FIG. 7 is the pseudo silicon wafer mentioned hereinabove. In this embodiment, a portion of each of the substrate layers 24′ is removed by grinding/polishing, and a substrate 24 is left, wherein the substrate 24 is surrounded and fixed by the molding compound structure layer 30′. Because the InP substrate has the high energy level, the infrared light having a wavelength longer than 1 μm can transmit through the InP substrate, thereby satisfying the light-transmission requirement of the embodiment. In addition, because the grinding/polishing process is adopted, the combination structure of FIG. 7 may have a flat top surface. Then, the combination structure of FIG. 7 may be subsequently treated or processed as an ordinary silicon wafer, wherein the subsequent treatment may include coating, etching, depositing, exposure, development and the like. It is understandable that the processor circuit 11 may be electrically connected to an external device through electrical connections applied to various silicon wafers. In one example, connection pads (not shown) on the top surface of the silicon-containing wafer 15′ may be adopted, wherein the connection pads covered by the molding compound structure layer 30′ may be exposed using laser to open the molding compound structure layer. In another example, connection pads (not shown) on the bottom surface of the silicon-containing wafer 15′ may be adopted using the technology of through-silicon via (TSV).

Next, as shown in FIG. 8, silicon wafer treating processes may be optionally adopted to manufacture an optical structure 40, including filters, collimators, light-shielding layers and/or micro lenses, on each of the substrates 24. Then, dicing is performed along the scribing lines D2 crossing the molding compound structure layer 30′, and the processor chips 10 are accordingly separated to form the optical assemblies 100 (see FIG. 1). Referring to FIGS. 8 and 1, the molding compound structure layer 30′ of FIG. 8 is diced into the molding compound layer 30 of FIG. 1. It is worth noting that the optical structure 40 is not necessary only formed in the region on the substrate 24. In some cases, the optical structure 40 may also be partially formed on the region of the molding compound layer 30 due to the manufacturing processes and the structural configuration. That is, the optical structure 40 may also be partially disposed on the molding compound layer 30, and this configuration is similarly applicable to the embodiment of FIG. 2.

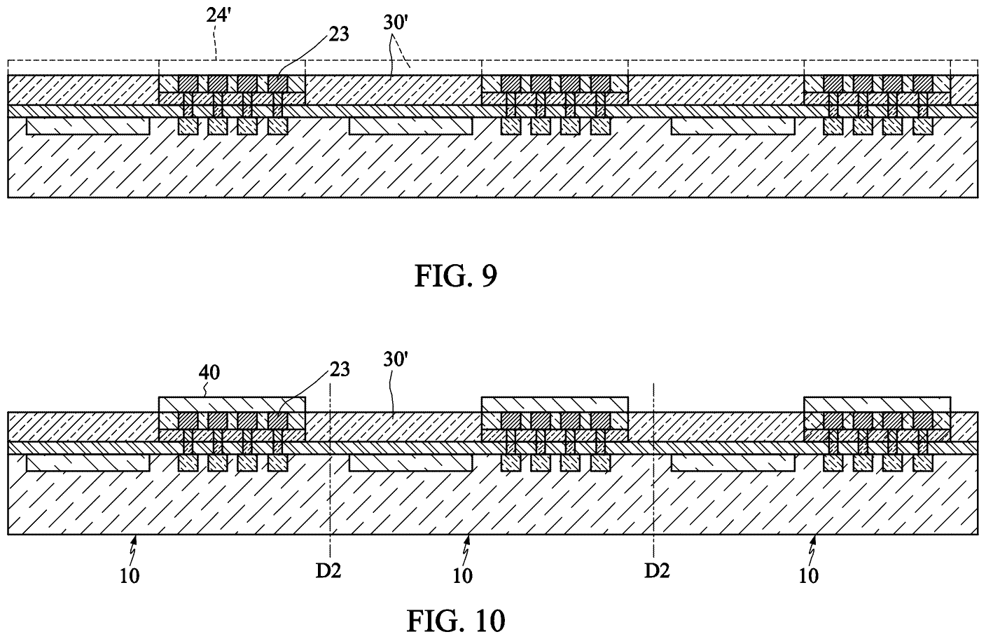

FIGS. 9 and 10 are schematic structure views showing a modified example of FIGS. 7 and 8. Referring to FIG. 9, a portion of the molding compound structure layer 30′ and almost a full portion of the substrate layer 24′ are removed, so that the optical pixels 23 are exposed. Referring to FIG. 10, the optical structures 40 are formed on the optical pixels 23, and then dicing is performed along the scribing lines D2 crossing the molding compound structure layer 30′, and the processor chips 10 are accordingly separated to form the optical assemblies 100 (see FIG. 2).

Although the above-mentioned embodiments are described according to the sensing pixels for sensing long-wavelength infrared light, the main technical feature of this disclosure still can be applied to other examples, wherein the reader circuit provides a control signal for controlling the optical pixels to perform one single or multiple optical processes including light-emitting, filtering, polarization, focusing, defocusing, reflection, diffraction and the like.

With the heterogeneously substrate-bonded optical assembly and the method of manufacturing the same according to the above-mentioned embodiments, the well-developed technology can be adopted to manufacture the complicated read-processing circuit on the silicon wafer, good optical chips may be formed using the non-silicon wafer, and then the optical chips and the read-processing circuit are combined. Next, the wafer-level manufacturing processes can be used to achieve the mass production, and the high-resolution and low-cost photosensor or other optical processors can be manufactured.

It is worth noting that all the above-mentioned embodiments can be combined, replaced or modified interactively as appropriate to provide diversified functions and satisfy diversified requirements.

The specific embodiments proposed in the detailed description of this disclosure are only used to facilitate the description of the technical contents of this disclosure, and do not narrowly limit this disclosure to the above-mentioned embodiments. Various changes of implementations made without departing from the spirit of this disclosure and the scope of the claims are deemed as falling within the following claims.

What is claimed is:

1. A heterogeneously substrate-bonded optical assembly, comprising:
a processor chip, comprising: a silicon-containing substrate; a processor circuit; reader circuits electrically connected to the processor circuit; a first protection layer disposed on the processor circuit and the reader circuits; and first vias penetrating through the first protection layer and being electrically connected to the reader circuits;
an optical chip containing a non-silicon substrate and comprising: a second protection layer bonded to the first protection layer; second vias penetrating through the second protection layer and being bonded to the first vias; and optical pixels formed in the non-silicon substrate, and electrically connected to the reader circuits respectively through the second vias and the first vias, wherein the optical pixels correspond to the reader circuits in a one-to-one manner, and a transversal dimension of the processor chip is greater than a transversal dimension of the optical chip; and
a molding compound layer surrounding the optical chip and being disposed on the first protection layer, wherein the molding compound layer has a top surface flush with a backside of the optical chip.

2. The optical assembly according to claim 1, wherein the first protection layer is fusion-bonded to the second protection layer, and the first vias are diffusion-bonded to the second vias.

3. The optical assembly according to claim 1, wherein a vertical boundary of the molding compound layer is aligned with a vertical boundary of the processor chip.

4. The optical assembly according to claim 1, wherein the molding compound layer has a molding compound structure having a dicing mark or dicing marks formed after wafer-level package dicing.

5. The optical assembly according to claim 1, wherein a transversal dimension of each of the optical pixels is smaller than or equal to 10 microns.

6. The optical assembly according to claim 1, wherein a transversal dimension of each of the first vias is smaller than or equal to 1 micron.

7. The optical assembly according to claim 1, further comprising an optical structure disposed on the backside of the optical chip.

8. The optical assembly according to claim 7, wherein the optical structure is selected from a group consisting of a collimator, a micro lens, a filter and a partial light shielding layer.

9. The optical assembly according to claim 7, wherein a portion of the optical structure is further disposed on the molding compound layer.

10. The optical assembly according to claim 1, wherein the optical pixels sense infrared light having a wavelength longer than 1 micron.

11. The optical assembly according to claim 1, wherein the optical pixels sense infrared light having a wavelength longer than 1.3 microns.

12. The optical assembly according to claim 1, wherein incident infrared light transmits through the non-silicon substrate and reaches the optical pixels.

13. The optical assembly according to claim 1 being selected from a group consisting of an optical sensor device, an optical filter, a polarizer, a curved-surface optical device, a digital optical device, a diffraction optical element and a metalens.

14. The optical assembly according to claim 1, wherein an outermost surface of the first protection layer is made of a material of silicon oxide or a silicon dioxide.

15. The optical assembly according to claim 1, wherein a transversal dimension of each of the optical pixels is smaller than or equal to 8 microns.

16. The optical assembly according to claim 1, wherein a transversal dimension of each of the optical pixels is smaller than or equal to 6 microns.

17. The optical assembly according to claim 1, wherein a transversal dimension of each of the optical pixels is smaller than or equal to 5 microns.

18. The optical assembly according to claim 1, wherein a transversal dimension of each of the first vias is equal to a transversal dimension of each of the second vias.

19. The optical assembly according to claim 1, wherein a transversal dimension of each of the first vias is different from a transversal dimension of each of the second vias.

20. The optical assembly according to claim 1, further comprising an optical structure disposed on or above the optical pixels, wherein optical devices of the optical structure correspond to the optical pixels in a one-to-one, one-to-many or many-to-many relationship.

21. The optical assembly according to claim 1, wherein the top surface of the molding compound layer and backsides of the optical pixels are disposed on a same plane.

22. The optical assembly according to claim 1, wherein the molding compound layer has a property of shielding infrared light.

23. The optical assembly according to claim 22, wherein the infrared light has a wavelength smaller than or equal to 20 μm.

24. A method of manufacturing a heterogeneously substrate-bonded optical assembly, the method comprising steps of:
(a) providing initial optical chips and a processing wafer, wherein:
each of the initial optical chips comprises: a non-silicon substrate layer; optical pixels formed on the non-silicon substrate layer; a second protection layer formed on the optical pixels; and second vias penetrating through the second protection layer and electrically connected to the optical pixels, respectively; and
the processing wafer has processor chips each comprising: a silicon-containing substrate; a processor circuit; reader circuits electrically connected to the processor circuit; a first protection layer disposed on the processor circuit and the reader circuits; and first vias penetrating through the first protection layer;
(b) respectively flipping and bonding the initial optical chips to the processor chips in an aligned manner, so that the optical pixels are electrically connected to the reader circuits through the second vias and the first vias, respectively;
(c) forming a molding compound structure layer on the initial optical chips and the processor chips;
(d) removing a portion of the molding compound structure layer and a portion of each of the initial optical chips; and
(e) dicing the molding compound structure layer and separating the processor chips to form optical assemblies, wherein in each of the optical assemblies, the optical pixels correspond to the reader circuits in a one-to-one manner, and a transversal dimension of the processor chip is greater than a transversal dimension of the initial optical chip.

25. The method according to claim 24, wherein in the step (d), a portion of each of the non-silicon substrate layers is removed and a non-silicon substrate is correspondingly left.

26. The method according to claim 25, further comprising, forming an optical structure on each of the non-silicon substrates in the step (d).

27. The method according to claim 24, wherein in the step (d), each of the non-silicon substrate layers is removed so that the optical pixels are exposed.

28. The method according to claim 27, further comprising: forming optical structures on the optical pixels in the step (d).

29. The method according to claim 24, wherein in the step (b), the first protection layer is fusion-bonded to the second protection layer, and the first vias are diffusion-bonded to the second vias.

30. The method according to claim 24, wherein each of the optical assemblies is selected from a group consisting of an optical sensor device, an optical filter, a polarizer, a curved-surface optical device, a digital optical device, a diffraction optical element and a metalens.
